(19) United States
(12) Patent Application Publication
(10) Pub. No.: US 2013/0157463 A1
(43) Pub. Date: Jun. 20, 2013

(54) NEAR-INFRARED ABSORBING FILM COMPOSITION FOR LITHOGRAPHIC APPLICATION

(71) Applicants: Dario L. Goldfarb, Dobbs Ferry, NY (US); Martin Glodde, Mahwah, NJ (US); Wu-Song Huang, Brewster, NY (US); Takeshi Kinsho, Joetsu-shi (JP); Wai-Kin Li, Beacon, NY (US); Kazumi Noda, Joetsu-shi (JP); Masaki Ohashi, Joetsu-shi (JP); Seiichiro Tachibana, Joetsu-shi (JP)

(72) Inventors: Dario L. Goldfarb, Dobbs Ferry, NY (US); Martin Glodde, Mahwah, NJ (US); Wu-Song Huang, Brewster, NY (US); Takeshi Kinsho, Joetsu-shi (JP); Wai-Kin Li, Beacon, NY (US); Kazumi Noda, Joetsu-shi (JP); Masaki Ohashi, Joetsu-shi (JP); Seiichiro Tachibana, Joetsu-shi (JP)

(73) Assignees: Shin-Etsu Chemical Co., Ltd., Tokyo (JP); INTERNATIONAL BUSINESS MACHINES CORPORATION, Armonk, NY (US)

(21) Appl. No.: 13/325,797

(22) Filed: Dec. 14, 2011

(51) Int. Cl. H01L 21/302; G03F 7/207; G02B 5/22

(52) U.S. Cl. 438/689; 252/587; 430/311; 257/E21.214

(57) ABSTRACT

The present invention relates to a near-infrared (NIR) film composition for use in vertical alignment and correction in the patterning of integrated semiconductor wafers and a pattern forming method using the composition. The NIR absorbing film composition includes a NIR absorbing dye having a polymethine cation and a crosslinkable anion, a crosslinkable polymer and a crosslinking agent. The patterning forming method includes aligning and focusing a focal plane position of a photoresist layer by sensing near-infrared emissions reflected from a substrate containing the photoresist layer and a NIR absorbing layer formed from the NIR absorbing film composition under the photoresist layer. The NIR absorbing film composition and the pattern forming method are especially useful for forming material patterns on a semiconductor substrate having complex buried topography.

### BACKGROUND OF THE INVENTION

This invention generally relates to photolithography, and more particularly to a near-infrared absorbing film composition for use in vertical alignment and correction in the patterning of integrated semiconductor wafers.

Photolithography is a process which uses light to transfer a geometric pattern from a photomask to a substrate such as a semiconductor wafer. In a photolithography process, a photoresist layer is first formed on the substrate. The substrate is baked to remove any solvent remained in the photoresist layer. The photoresist is then exposed through a photomask with a desired pattern to a source of actinic radiation. The radiation exposure causes a chemical reaction in the exposed areas of the photoresist and creates a latent image corresponding to the mask pattern in the photoresist layer. The photoresist is next developed in a developer solution, usually an aqueous base solution, to form a pattern in the photoresist layer. The patterned photoresist can then be used as a mask for subsequent fabrication processes on the substrate, such as deposition, etching, or ion implantation processes.

In the photolithography process described above, the substrate on which the photoresist is formed often has complex buried topography. Such buried topography usually includes a multilayer stack that contains metal, dielectric, insulator or ceramic materials and combinations thereof which are patterned and provide vertical and in-plane functionality to the chip. Patterning the photoresist over such a multilayer stack requires wafer pre-alignment such that a properly focused and registered image is latently formed within the photoresist layer.

To provide for such a pre-alignment, the state of art exposure systems have an auto focus leveling sensor system to adjust the wafer in vertical direction (perpendicular to the photoresist surface). The leveling sensor system uses an incident vertical alignment beam which usually comes from a broad band NIR light source. The incident vertical alignment beam impinges upon the substrate and is reflected from the substrate. The reflected vertical alignment beam is received by a vertical alignment beam detector to detect the distance between the photoresist surface and the exposure lens and adjust the vertical height (Z height) of the wafer to get the best focus for the exposure.

In cases where the substrate has complex buried topography, the vertical alignment beam is also reflected from the multilayer stack, leading to secondary and/or tertiary reflected lights. These secondary and tertiary reflected lights may interfere with the regularly reflected vertical alignment beam signal and create errors in the Z height adjustment. The improper Z height adjustment leads to focus error, degrades the lithographic process window, and decreases the yield of the final products. Thus, there is a need for materials and methods for proper vertical alignment and correction in patterning integrated semiconductor wafers.

### SUMMARY OF THE INVENTION

The present invention provides a near-infrared (NIR) absorbing film composition containing one or more dyes which have an absorption range partially or completely covering the auto focus leveling sensor signal in the NIR region. Such a composition can be used to form a NIR absorbing layer between a photoresist layer and the semiconductor substrate underlying the photoresist layer. The NIR absorbing layer blocks the incident vertical alignment beam after it passes through the photoresist layer and prevents the secondary and/or tertiary reflected lights from the multilayer stack in the substrate by absorption, thus enables proper vertical alignment and correction in patterning integrated semiconductor wafers.

In one aspect, the present invention relates to a NIR absorbing film composition for use in photolithography including a NIR absorbing dye having a polymethine cation and a crosslinkable anion, a crosslinkable polymer and a crosslinking agent. In one embodiment, the crosslinkable anion includes a hydroxyl, a carboxyl, a reactive ether, an amino or an imino group. In another embodiment, the crosslinkable anion also includes an aromatic group. The NIR absorbing film composition may further includes an acid generator and a casting solvent.

In another aspect, the present invention relates to a method of forming a patterned feature on a substrate. The method includes the steps of: providing a material layer on a substrate; forming a NIR absorbing layer from a NIR absorbing film composition on the material layer, wherein the NIR absorbing film composition includes a NIR absorbing dye having a polymethine cation and a crosslinkable anion, a crosslinkable polymer and a crosslinking agent; forming a photoresist layer over the NIR absorbing layer; aligning and focusing a focal plane position of the photoresist layer by sensing near-infrared emissions reflected from the substrate containing the NIR absorbing layer and photoresist layer; patternwise exposing the photoresist layer to radiation; and selectively removing a portion of the photoresist layer to form the patterned feature in the photoresist layer. In one embodiment, the crosslinkable anion includes a hydroxyl, a carboxyl, a reactive ether, an amino or an imino group. In another embodiment, the crosslinkable anion also includes an aromatic group. The NIR absorbing film composition may further includes an acid generator and a casting solvent. The method may further include the step of transferring the patterned feature to the material layer by etching or ion implanting the exposed portion of the material layer.

### DETAILED DESCRIPTION OF PREFERRED EMBODIMENTS

It will be understood that when an element, such as a layer, is referred to as being “on” or “over” another element, it can be directly on the other element or intervening elements may also be present. In contrast, when an element is referred to as being “directly on” or “directly over” another element, there are no intervening elements present.

As discussed above, when a semiconductor substrate has complex buried topography (e.g., multilayer stack), the vertical alignment beam used for pre-alignment is reflected not only from the photoresist layer, but also from the underlying multilayer stack, leading to secondary and/or tertiary reflected lights. These secondary and tertiary reflected lights may interfere with the regularly reflected vertical alignment beam signal from the photoresist layer and lead to vertical misalignment of the substrate. To address this problem, the present invention provides a NIR absorbing film composition for forming a NIR absorbing layer between the photoresist layer and the semiconductor substrate. In particular, the NIR absorbing film composition of the present invention includes a NIR absorbing dye having a polymethine cation and a crosslinkable anion, a crosslinkable polymer and a crosslinking agent. The polymethine containing dye offers effective NIR blocking capability. In addition, the anionic part of one NIR absorbing dye molecule can react with the crosslinking agent to crosslink with the crosslinkable polymer and/or other NIR absorbing dye molecules to form a crosslinked network. The crosslinking of the anionic part of the NIR absorbing dye molecule with the polymer and/or other NIR absorbing dye molecules enhances the processability of the NIR absorbing film solvent resistance to wetting solvents and/or resist casting solvents).

In a preferred embodiment, the crosslinkable anion of the NIR absorbing dye is a monovalent organic acid anion. Most preferably, the crosslinkable anion is based on sulfonate (SO₃⁻) functionality. In addition, the crosslinkable anion of the NIR absorbing dye preferably contains a hydroxyl, a carboxyl, a reactive ether, an amino or an imino group. The foregoing groups can react with a crosslinking agent in a manner which is catalyzed by acid and/or by heating and render the anion crosslinkable. Furthermore, it is preferred that the anion of the NIR absorbing dye contains an aromatic group. The aromatic group enhances the etch resistance of the NIR absorbing film toward plasma such as oxygen containing plasma and enables successful transfer of the pattern formed in the photoresist layer to an underlying material layer in a subsequent etch transfer process. In addition, the aromatic group also increases the absorption of the NIR absorbing film at the imaging wavelength of the overlying photoresist. The crosslinkable anion may have the following general structure:

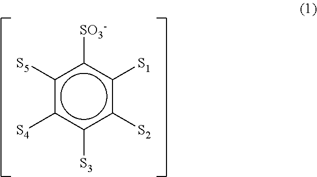

where S₁ to S₅ are the same or different and each independently represents a hydrogen atom, a linear or branched alkyl, a linear or branched alkoxy or a hydroxyl group, provided that at least one of S₁ to S₅ is a hydroxyl group.

Some particular examples of crosslinkable anions suitable for use in the NIR absorbing dye according to the present invention include:

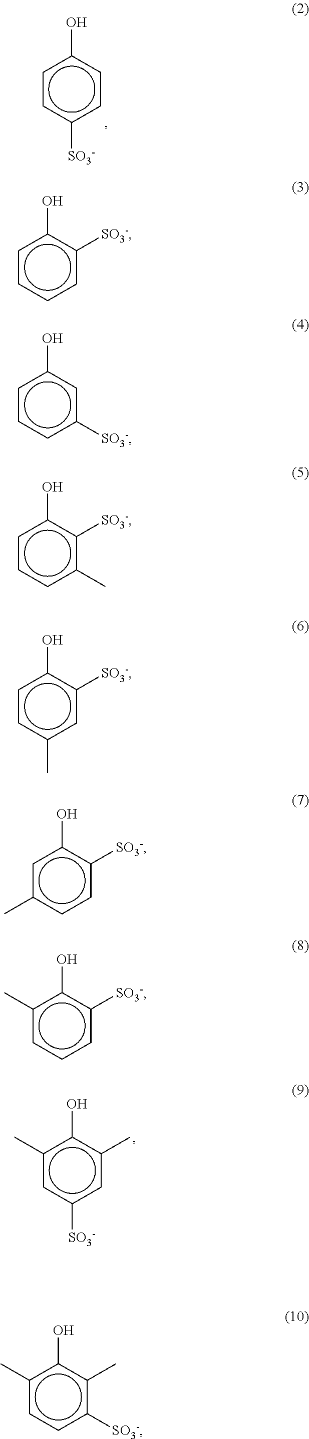

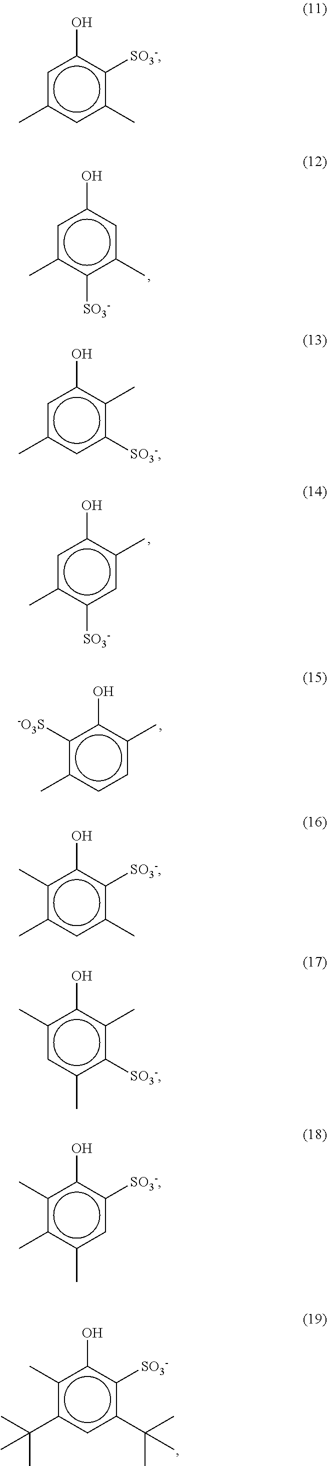

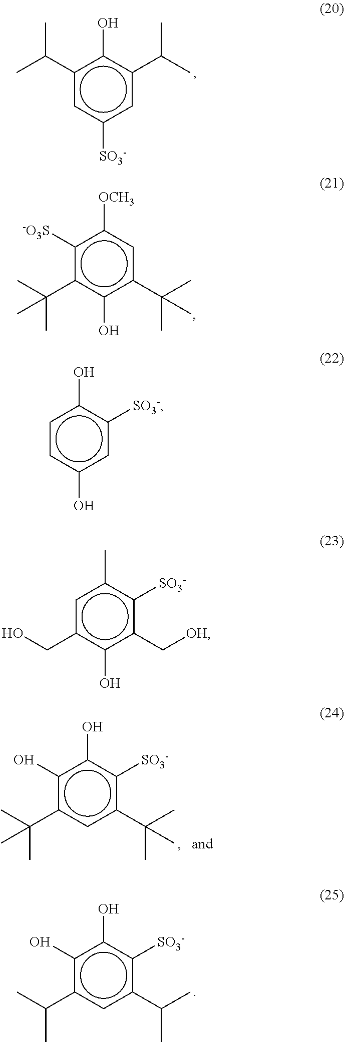

The polymethine cation of the NIR absorbing dye preferably has the following general structure:

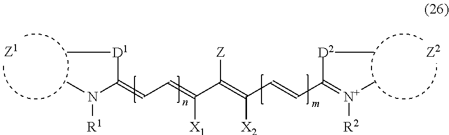

where m and n are the same or different and each independently represents an integer from 0 to 2; Z represents a hydrogen atom, a halide atom, a linear, branched, cyclic or polycyclic saturated or unsaturated group containing 1 to 25 carbon atoms, wherein the linear, branched, cyclic or polycyclic saturated or unsaturated group optionally includes one or more heteroatoms selected from nitrogen, oxygen, sulfur and halide atoms; X₁ and X₂ are the same or different and each independently represents a hydrogen atom, a halide atom or a linear, branched or cyclic group containing 1 to 6 carbon atoms, wherein when X₁ and X₂ are linear and branched group containing 1 to 6 carbon atoms, they can interconnect to form a five- or six-membered ring; R₁ and R₂ are the same or different and each independently represents a linear or branched alkyl group containing 1 to 6 carbon atoms, a linear or branched alkoxyalkyl group containing 1 to 6 carbon atoms or a linear or branched hydroxyalkyl group containing 1 to 6 carbon atoms; D₁ and D₂ are the same or different and each independently represents —O—, —S—, —Se—, —CH═CH—, —C(CH₃)₂—, or —C—; and Z₁ and Z₂ are the same or different and each independently represents one or more fused substituted or unsubstituted aromatic rings, wherein when D₁ is —C—, interconnects with Z₁ to form one or more fused substituted or unsubstituted aromatic rings and when D₂ is —C—, D₂ interconnects with Z₂ to form one or more fused substituted or unsubstituted aromatic rings.

Some particular examples of polymethine cations suitable for use in the NIR absorbing dye according to the present invention include:

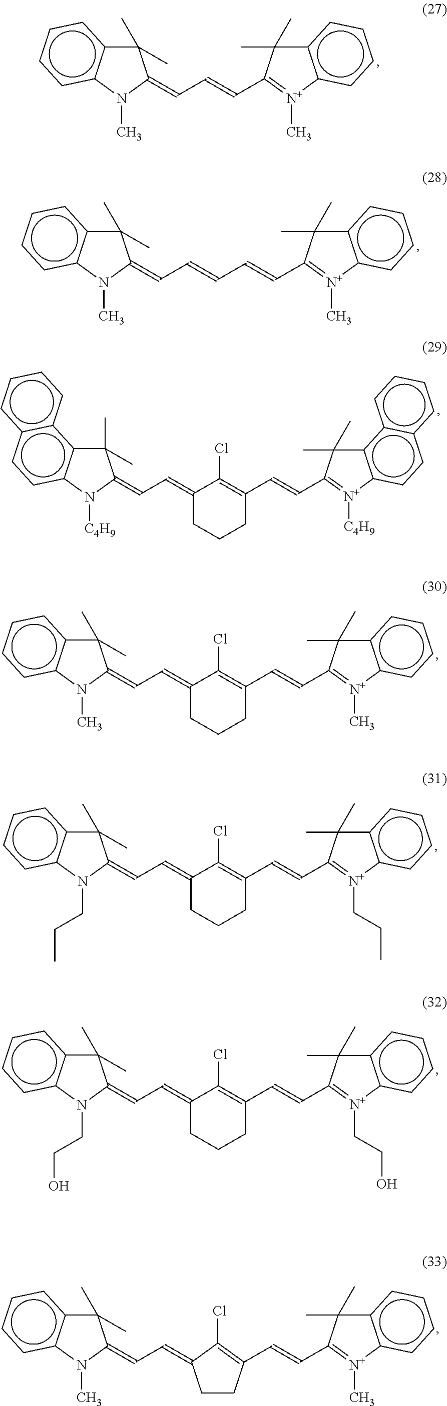

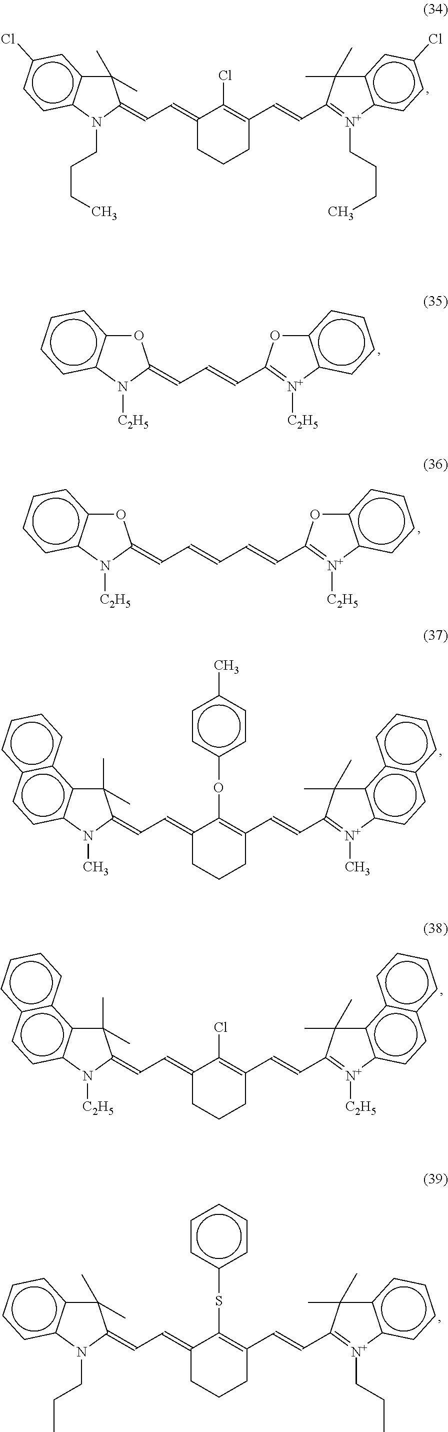

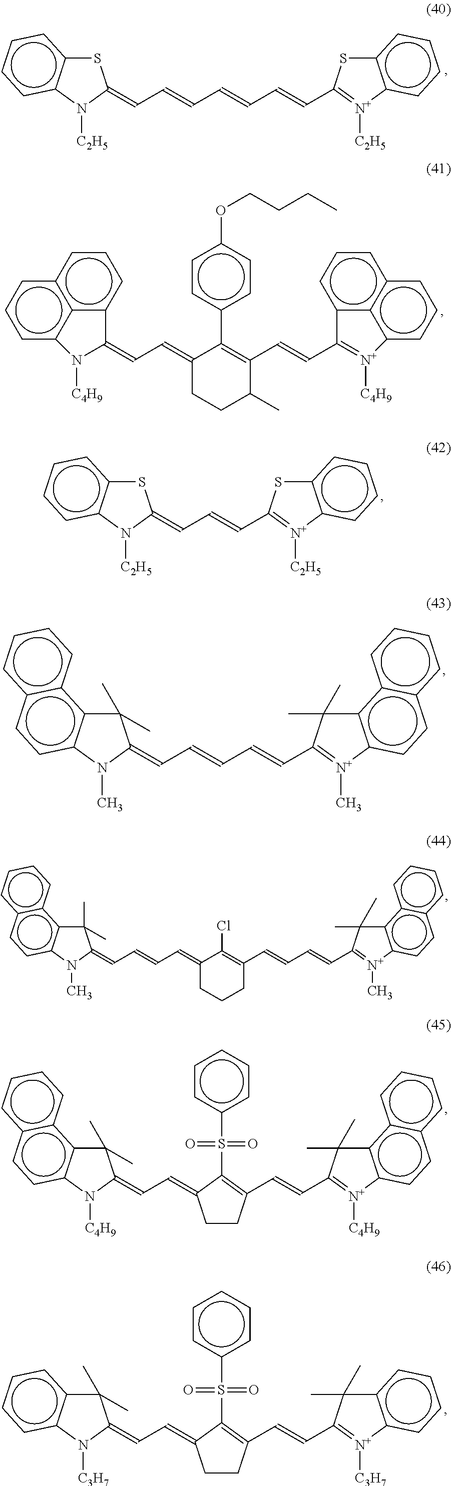

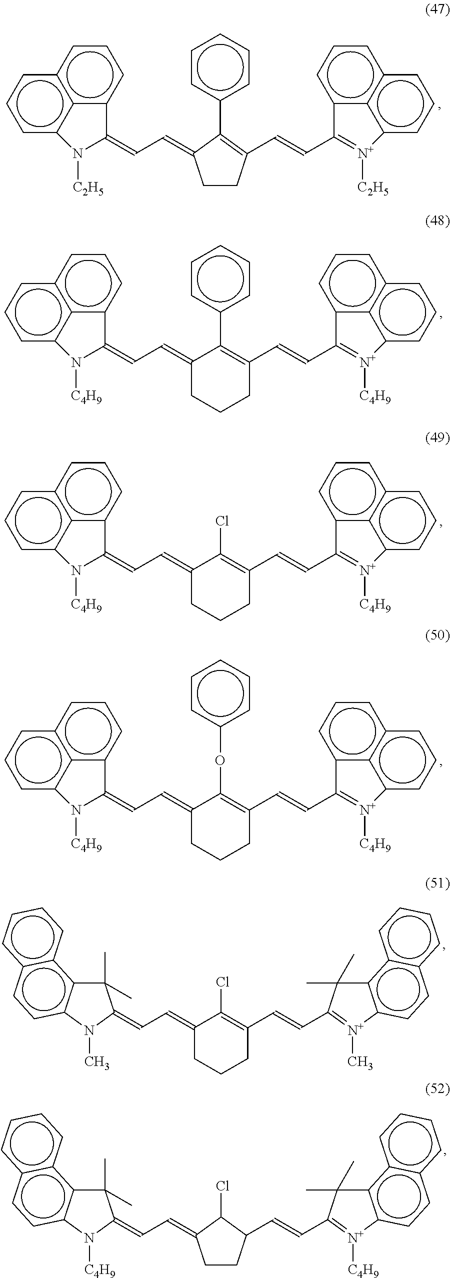

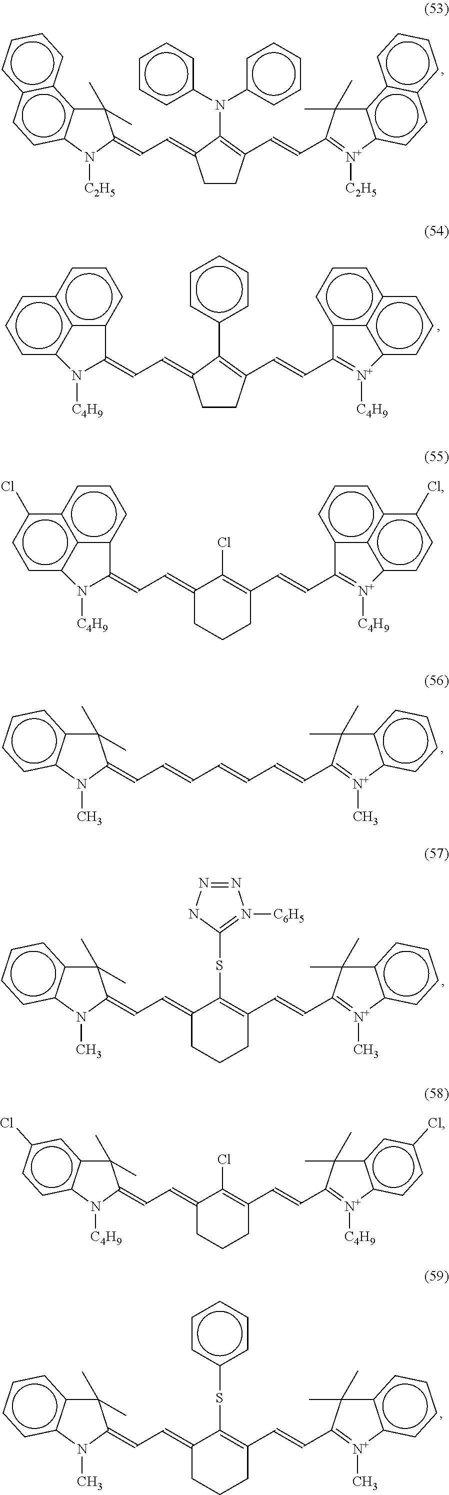

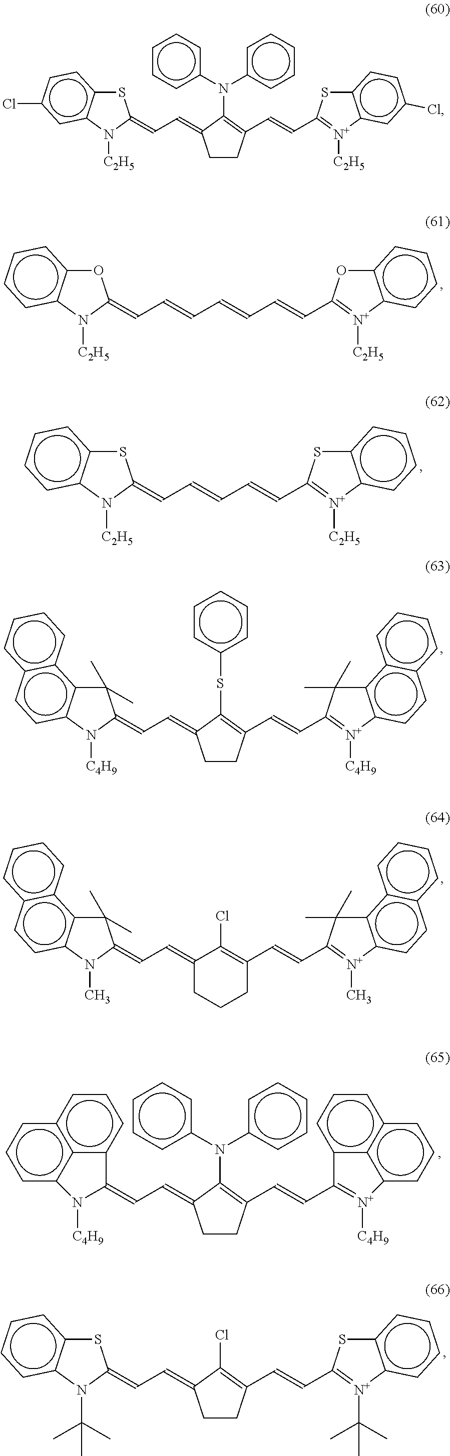

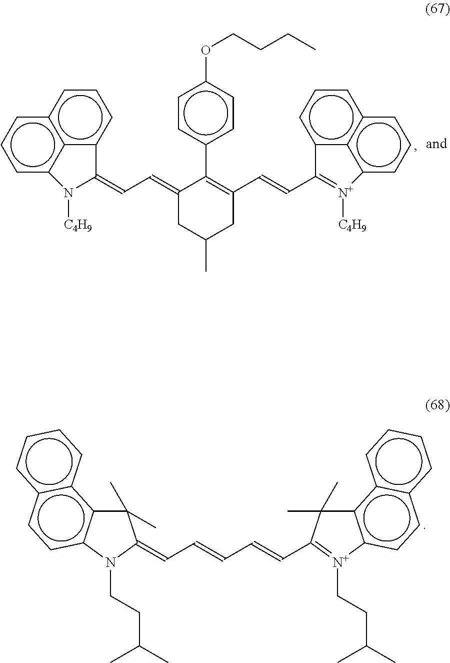

The NIR absorbing dye absorbs NIR wavelengths of electromagnetic radiation. The NIR wavelengths being considered herein broadly encompass any of the wavelengths between 500 nm and 5000 nm. Preferably, the NIR absorbing dye has at least one absorption peak between 500 nm and 1200 nm. The NIR absorbing film composition may contain more than one NIR absorbing dyes.

The NIR absorbing film composition of the present invention further includes a crosslinkable polymer. The crosslinkable polymer can be any polymer which can be crosslinked by any of the means known in the art (e.g., by chemical, thermal or radiative curing methods). The crosslinkable polymer can be a homopolymer of a single monomer unit or a copolymer, terpolymer or higher-order polymer of two or more different monomer units. The monomer units of the crosslinkable polymer are derived from monomers having a polymerizable moiety. Examples of the polymerizable moiety may include:

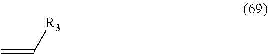

where R₃ represents hydrogen, a linear or branched alkyl group of 1 to 20 carbons, a semi- or perfluorinated linear or branched alkyl group of 1 to 20 carbons, or CN; and

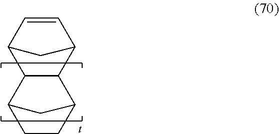

where t is an integer from 0 to 3.

Preferably, the crosslinkable polymer includes a monomer unit having a hydroxyl, a carboxyl, a reactive ether, an amino or an imino group. The foregoing groups can react with a crosslinking agent in a manner which is catalyzed by acid and/or by heating and make the polymer crosslinkable. More preferably, the crosslinkable polymer includes a monomer unit containing a hydroxyl or a reactive ethet group.

Some particular examples of monomer units suitable for use in the crosslinkable polymer according to the present invention include:

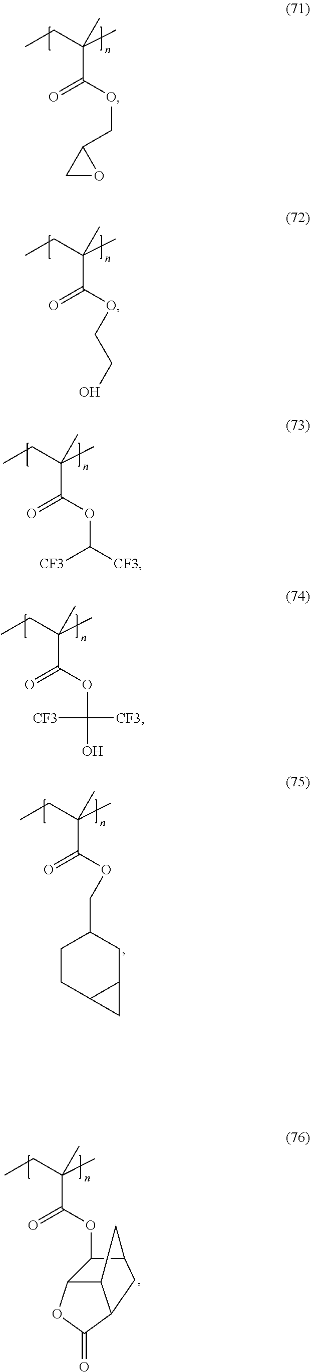

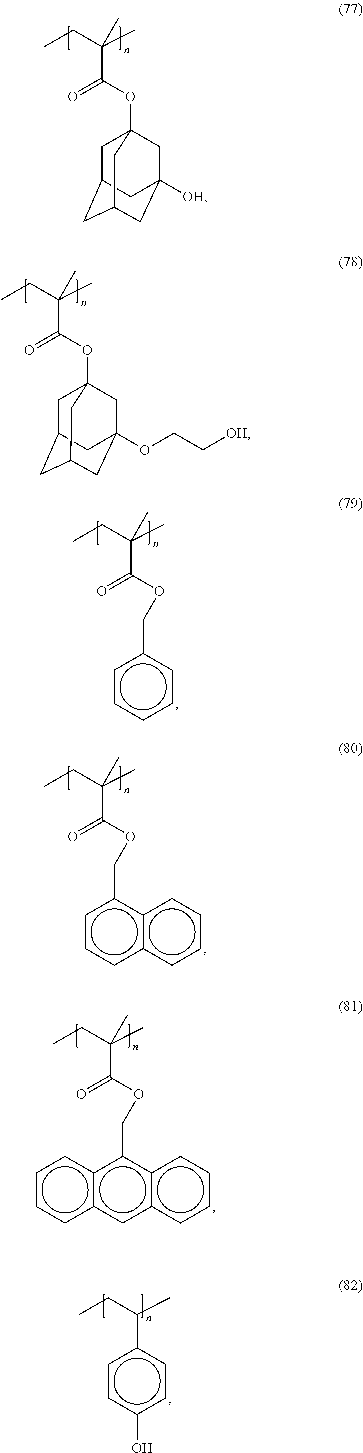

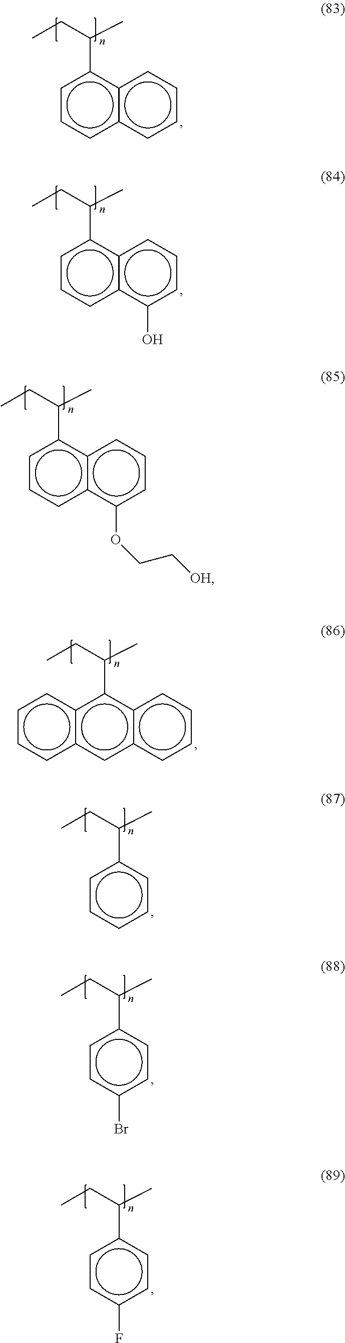

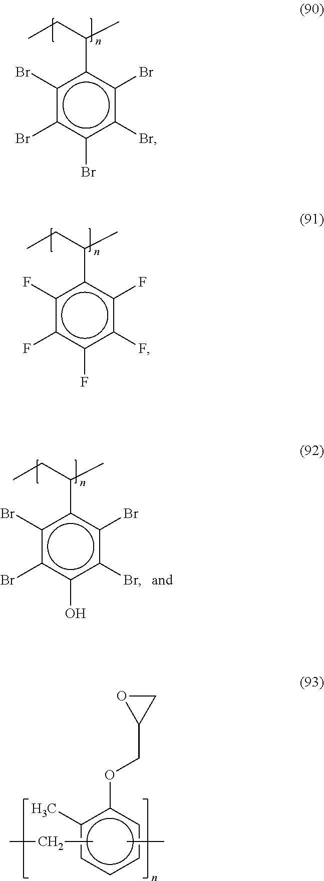

The crosslinkable polymer may be a homopolymer of one of the monomer units listed above. It may be a copolymer, terpolymer or higher-order polymer of two or more of the monomer units listed above. In addition, the crosslinkable polymer may be a copolymer, terpolymer or higher-order polymer of any one of the monomer units listed above and other monomer units. The NIR absorbing film composition may include more than one crosslinkable polymers.

The NIR absorbing film composition also includes a crosslinking agent. The crosslinking agent can react with the NIR absorbing dye and/or the crosslinkable polymer in a manner which is catalyzed by acid and/or by heating to interlink the NIR absorbing dye molecules and/or the crosslinkable polymer chains. Generally, the crosslinking agent of the NIR absorbing film composition of the present invention is any suitable crosslinking agent known in the negative photoresist art which is compatible with the other selected components of the composition. The crosslinking agent typically acts to crosslink the NIR absorbing dye and/or the crosslinkable polymer in the presence of a generated acid. Typical crosslinking agents are glycoluril compounds such as tetramethoxymethyl glycoluril, methylpropyltetramethoxymethyl glycoluril, and methylphenyltetramethoxymethyl glycoluril, available under the POWDERLINK® trademark from Cytec Industries. Other possible crosslinking agents include: 2,6-bis(hydroxymethyl)-p-cresol compounds such as those disclosed in Japanese Laid-Open Patent Application (Kokai) No. 1-293339, etherified amino resins, for example, methylated or butylated melamine resins (N-methoxymethyl- or N-butoxymethyl-melamine respectively), and methylated/butylated glycolurils, for example as disclosed in Canadian Patent No. 1 204 547. Other crosslinking agents such as bis-epoxies or bis-phenols (e.g., bisphenol-A) may also be used. Combinations of two or more crosslinking agents may be preferred in some embodiments.

Some particular examples of crosslinking agents suitable for use in the NIR absorbing film composition according to the present invention include:

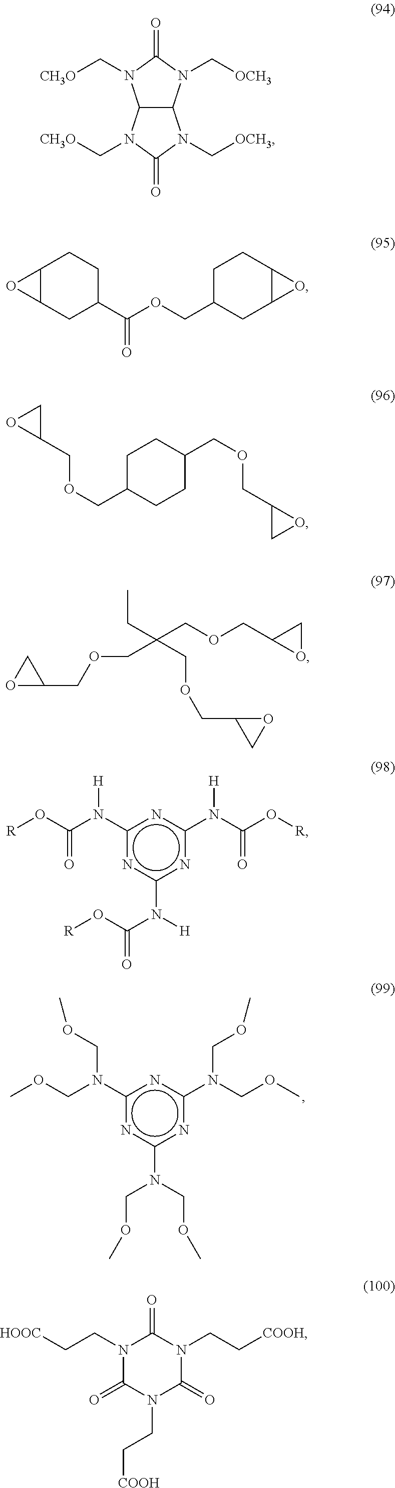

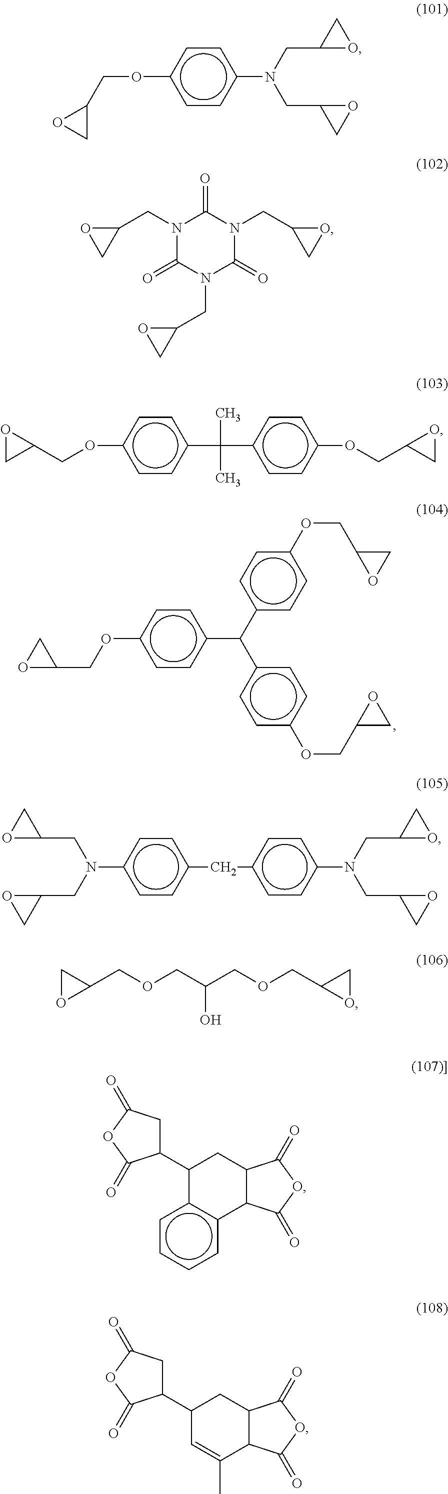

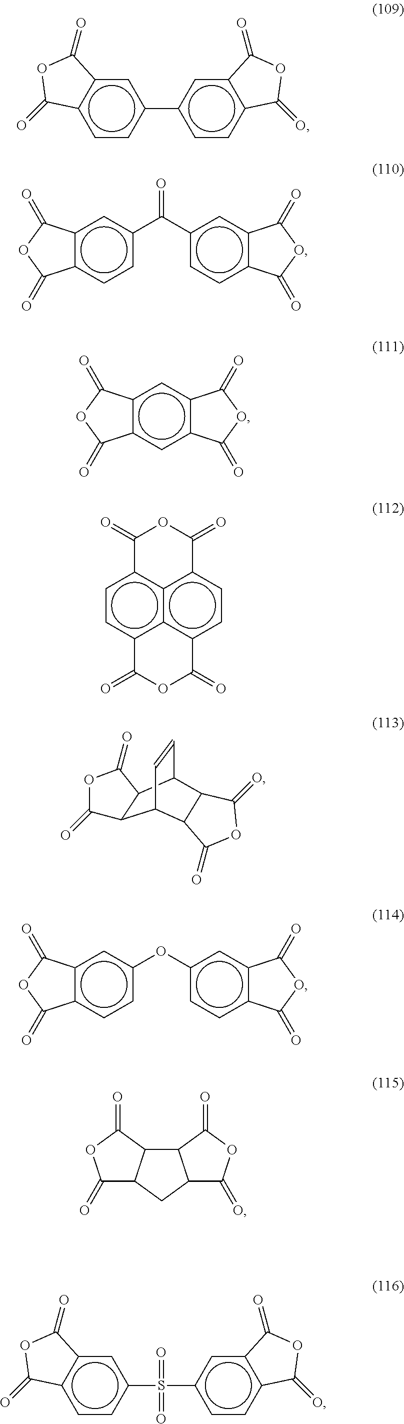

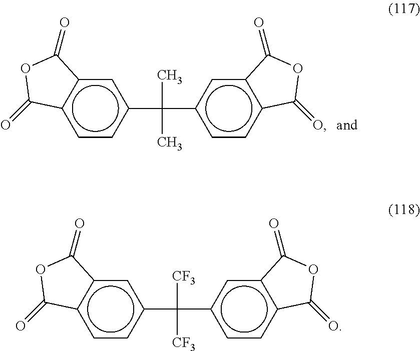

Optionally, the NIR absorbing film composition may also include an acid generator for facilitating the crosslinking process. The acid generator is typically a thermal acid generator that liberates acid upon thermal treatment. Acid generators that generate a sulfonic acid group upon heating are generally suitable. Some examples of thermal acid generators include 2,4,4,6-tetrabromocycloftexadienone, benzoin tosylate, 2-nitrophenyl tosylate, and other alkyl esters of organic sulfonic acids. Other suitable thermally activated acid generators are described in U.S. Pat. Nos. 5,886,102 and 5,939,236. If desired, a photo acid generator (PAG) may be employed as an alternative to a thermally activated acid generator or in combination with a thermally activated acid generator. Examples of suitable PAGs are also described in U.S. Pat. Nos. 5,886,102 and 5,939,236. Other PAGs known in the resist art may also be used as long as they are compatible with the other components of the NIR absorbing film composition. Where a PAG is used, the crosslinking temperature of the NIR absorbing film composition may be reduced by application of appropriate radiation to induce acid generation. Even if a PAG is used, it may be preferred to thermally treat the composition to accelerate the crosslinking process. In some embodiments, mixtures of acid generators may be used.

Some particular examples of acid generators suitable for use in the NIR absorbing film composition according to the present invention include:

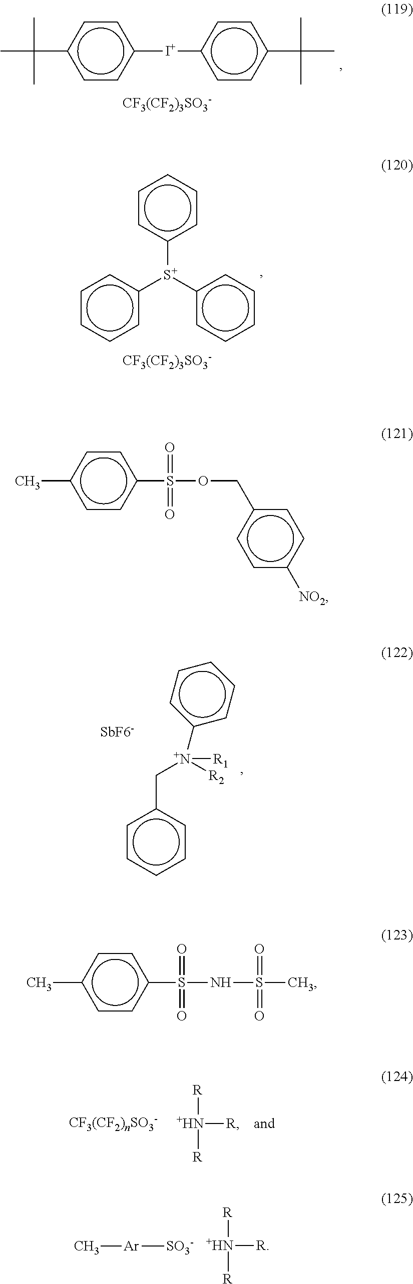

The NIR absorbing film composition of the present invention may further include a casting solvent, and other performance enhancing additives, for example, a quencher and a surfactant. Solvents well known to those skilled in the art may be employed in the NIR absorbing film composition of various exemplary embodiments of the present invention. Such solvents may be used to dissolve the NIR absorbing dye and the crosslinkable polymer and other components of the NIR absorbing film composition. Illustrative examples of such solvents may include, but are not limited to: 3-pentanone, Methyl Isobutyl Ketone (MIBK), Propylene glycol methyl ether (1-Methoxy-2-propanol); Methyl Cellos® lye (2-Methoxyethanol) Butyl Acetate, 2-ethoxyethanol, Propylene glycol methyl ether acetate (PGMEA), Propylene glycol propyl ether (1-Propoxy-2-propanol, PnP), 4-heptanone, 3-heptanone, 2-heptanone, N,N-dimethylformamide, Anisole, Ethyl Lactate, Cyclohexanone, Cellosolve Acetate (Ethylene glycol ethyl ether acetate) N,N-dimethylacetamide, Diglyme (2-methoxy ethyl ether), Ethyl 3-ethoxy propionate, Dimethyl Sulfoxide, Di (propylene glycol) methyl ether (DOWANOL), Di (ethylene glycol) methyl ether, Diethylmalonate, 2-(2-butoxy ethoxy ethanol) (DEGBE) and gamma-butyrolactone.

The amount of solvent in the NIR absorbing film composition is typically selected such that a solid content of about 1-20 wt. % is achieved. Higher solid content formulations will generally yield thicker coating layers. In some embodiments, mixtures of solvents may be used.

The quencher that may be used in the NIR absorbing film composition of the present invention may comprise a weak base that scavenges trace acids, white not having an excessive impact on the performance of the MR absorbing film composition. Illustrative examples of quenchers that can be employed in the present invention include, but are not limited to: aliphatic amines, aromatic amines, carboxylates, hydroxides, or combinations thereof and the like.

The optional surfactants that can be employed in the NIR absorbing film composition include any surfactant that is capable of improving the coating homogeneity of the NIR absorbing film composition of the present invention. Illustrative examples include: fluorine-containing surfactants such as 3M's FC-443® and siloxane-containing surfactants such as Union Carbide's Silwet® series.

The present invention also encompasses a method of using the NIR absorbing film composition described above to form a patterned feature on a substrate. In one embodiment, such a method includes the steps of: providing a material layer on a substrate; forming a NIR absorbing layer from a NIR absorbing film composition on the material layer, wherein the NIR absorbing film composition includes a NIR absorbing dye having a polymethine cation and a crosslinkable anion, a crosslinkable polymer and a crosslinking agent; forming a photoresist layer over the NIR absorbing layer; aligning and focusing a focal plane position of the photoresist layer by sensing near-infrared emissions reflected from the substrate containing the NIR absorbing layer and photoresist layer; patternwise exposing the photoresist layer to radiation; and selectively removing a portion of the photoresist layer to form the patterned feature in the photoresist layer.

In various exemplary embodiments of the present invention, the substrate is suitably any substrate conventionally used in processes involving photoresists. For example, the substrate can be silicon, silicon oxide, aluminum-aluminum oxide, gallium arsenide, ceramic, quartz, copper or any combination thereof, including multilayers. The substrate can include one or more semiconductor layers or structures and can include active or operable portions of semiconductor devices.

The material layer may be a metal conductor layer, a ceramic insulator layer, a semiconductor layer or other material depending on the stage of the manufacture process and the desired material set for the end product. The NIR absorbing film composition of the present invention is especially useful for lithographic processes used in the manufacture of integrated circuits on semiconductor substrates. The NIR absorbing film composition of the invention can be used in lithographic processes to create patterned material layer structures such as metal wiring lines, holes for contacts or vias, insulation sections (e.g., damascene trenches or shallow trench isolation), trenches for capacitor structures, ion implanted semiconductor structures for transistors, etc. as might be used in integrated circuit devices.

The material layer is then covered by a NIR absorbing layer formed from the NIR absorbing film composition described above. The NIR absorbing layer can be formed by any of the techniques known in the art including spin coating. After formation, the NIR absorbing layer may be baked to remove any remaining solvent from the NIR absorbing layer and to cure the NIR absorbing layer (i.e., to crosslink various components of the NIR absorbing film composition). The preferred range of the bake temperature for the NIR absorbing layer is from about 110° C. to about 27° C., more preferably from about 180° C. to about 25° C. The preferred range of thickness of the NIR absorbing layer is from about 25 nm to about 500 nm, more preferably from about 50 nm to about 200 nm. The NIR absorbing layer preferably has a k value greater than 0.15 at its absorption maximum between 500 nm and 1200 nm, more preferably greater than 0.5 at its absorption maximum between 500 nm and 1200 nm.

A photoresist layer is then formed over the NIR absorbing layer. The photoresist layer can be formed from any positive or negative photoresists known in the art. The photoresist layer may be formed by virtually any standard means including spin coating. The photoresist layer may be baked (post applying bake (PAB)) to remove any solvent from the photoresist and improve the coherence of the photoresist layer. The preferred range of the PAB temperature for the photoresist layer is from about 70° C. to about 150° C., more preferably from about 90° C.: to about 130° C. The preferred range of thickness of the first layer is from about 20 nm to about 400 nm, more preferably from about 30 nm to about 300 nm.

The NIR absorbing layer in the present invention typically functions as an anti-reflective layer, such as a bottom anti-reflective coating (BARC) layer, a planarization underlayer (UL) or an extra interlayer. In one embodiment, the photoresist layer directly covers the NIR absorbing layer. In another embodiment, the photoresist layer does not directly cover the NIR absorbing layer by having one or more intervening layers between the photoresist layer and the NIR absorbing layer. In addition, intervening layers may also be present between the material layer and the NIR absorbing layer. In another embodiment, the NIR absorbing layer described above includes a photoimageable component such that the NIR absorbing layer is also the photoresist layer (i.e., the NIR absorbing layer and the photoresist layer become one layer).

In addition, one or more other films can cover the photoresist layer. An example of such a film used for covering the photoresist layer is an immersion topcoat film. An immersion top coat film typically functions to prevent components of the photoresist layer from leaching into an immersion medium, such as water.

To properly align and focus a focal plan position of the photoresist layer, a focus leveling sensor light is emitted from a broad band NIR source. The focus leveling sensor light impinges upon and is reflected from the substrate. The reflected light is then detected by a leveling photosensor followed by an auto focus mechanism which adjusts the z height to place the photoresist layer within the imaging focal plane. Any NIR light reflected from the multilayer stack structures in the substrate will interfere with the surface reflected light and cause a wrong adjustment in z height. The incorporation of the NIR-absorbing layer advantageously substantially minimizes or removes reflected or diffracted infrared wavelengths emanating from buried topography of the underlying substrate. Accordingly, a much more accurate sensing of the top wafer surface is made possible. The improved sensing of the top surface allows for a more accurate placement of surface features or surface operations (e.g., patterning of the photoresist layer).

The photoresist layer is then patternwise exposed to a desired radiation. The radiation employed in the present invention can be visible light, ultraviolet (UV), extreme ultraviolet (EUV) and electron beam (E-beam). It is preferred that the imaging wavelength of the radiation is about 248 nm, 193 nm or 13 nm. It is more preferred that the imaging wavelength of the radiation is about 193 nm (ArF laser). The patternwise exposure is conducted through a mask which is placed over the photoresist layer.

After the desired patternwise exposure, the photoresist layer is typically baked (post exposure bake (PEB)) to further complete the acid-catalyzed reaction and to enhance the contrast of the exposed pattern. The preferred range of the PEB temperature is from about 70° C. to about 150° C., more preferably from about 90° C. to about 13° C. In some instances, it is possible to avoid the PEB step since for certain chemistries, such as acetal and ketal chemistries, deprotection of the resist polymer proceeds at room temperature. The post-exposure bake is preferably conducted for about 30 seconds to 5 minutes.

After PEB, if any, the photoresist structure with a desired pattern is obtained by contacting the photoresist layer with a developer to selectively remove a portion of the photoresist layer. Any developer known in the art may be used in the present invention, including an aqueous base developer and an organic solvent developer.

The pattern from the photoresist structure may then be transferred to the underlying material layer of the substrate by etching with a suitable etchant using techniques known in the art; preferably the transfer is done by reactive ion etching or by wet etching. Once the desired pattern transfer has taken place, any remaining photoresist may be removed using conventional stripping techniques. Alternatively, the pattern may be transferred by ion implantation to form a pattern of ion implanted material.

Examples of general lithographic processes where the composition of the invention may be useful are disclosed in U.S. Pat. Nos. 4,855,017; 5,362,663; 5,429,710; 5,562,801; 5,618,751; 5,744,376; 5,801,094; 5,821,469 and 5,948,570. Other examples of pattern transfer processes are described in Chapters 12 and 13 of “Semiconductor Lithography, Principles, Practices, and Materials” by Wayne Moreau, Plenum Press, (1988). It should be understood that the invention is not limited to any specific lithography technique or device structure.

The invention is further described by the examples below. The invention is not limited to the specific details of the examples.

### Example 1

### Synthesis of a NIR Absorbing Dye of the Invention: IR-780 having 4-Hydroxybenzenesulfonate Anion (E)

6.25 g (0.0359 mol) of 4-hydroxybenzenesulfonic acid (A) was dissolved in 15 g of DI H₂O. The solution was added to silver carbonate (B) (5 g, 0.363 mol equivalents of Ag+ cation). The resulting suspension was stirred for 2 hrs and filtered through a nylon membrane (0.2 micron pore size) to remove unreacted silver carbonate. The solvent from the filtered solution was removed using a rotary evaporator. The remaining solid was dried in a vacuum oven overnight, yielding 10.0 g of Silver 4-hydroxybenzenesulfonate (C) (yield: 99%).

0.5 g (7.5×10⁻⁴ mol) of NIR dye IR-780 iodide (D) (commercially available from Aldrich® Chemistry) was dissolved in acetonitrile (20 g) by stirring. To this solution, a solution of silver 4-hydroxybenzenesulfonate (C) (0.225 g, 8×10⁻⁴ mot) in 20 g of acetonitrile was added dropwise and stirred vigorously for 1 hr. The precipitated silver iodide was filtered through a PIPE membrane (0.2 micron pore size). The solvent from the filtered solution was removed using a rotary evaporator. The remaining solid was dried in a vacuum oven overnight, yielding 0.4 g of IR-780 having 4-hydroxybenzenesulfonate anion (E) (yield: 75%). The absence of iodide anion in the final product was confirmed by casting a film of the NIR dye bearing the 4-hydroxybenzenesulfonate onto a silicon wafer and performing TXRF (Total Reflection X-ray Fluorescence) analysis.

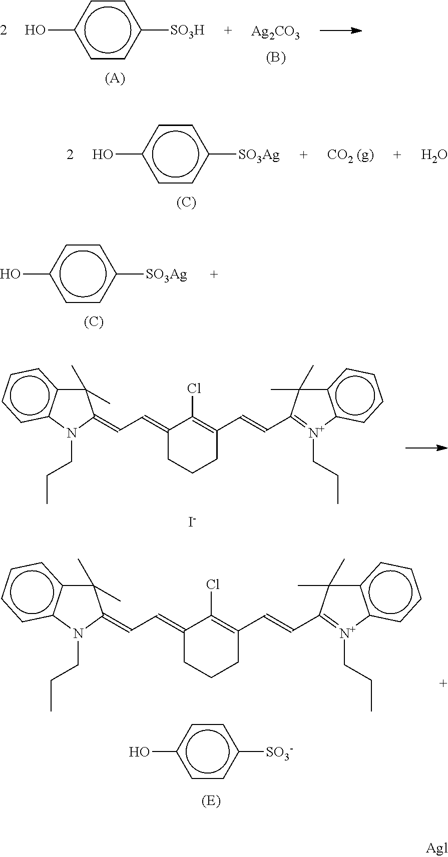

### TXRF Results (10¹⁰ atoms/cm²)

| Element | IR-780 4-hydroxybenzenesulfonate |
|---|---|
| S | 13300 |
| I | 12700 |
| Cl | ND |
| Ag | ND |

### Example 2

### Formulation of a NIR Absorbing Film Composition of the Invention

NIR absorbing dye IR-7804-hydroxybenzenesulfonate (prepared as described in Example 1) and poly(4-hydroxystyrene) polymer (Mw=15 k) were dissolved at variable mass ratios totaling 4.8 parts by weight in cyclohexanone. The variable mass ratios were 10:90, 20:80, 30:70, 40:60 and 50:50. A thermal acid generator consisting of triethylammonium nonafluorobutane sulfonate was added to the solution in a concentration of 5 parts by weight with respect to the formerly described solids. Similarly, a crosslinking agent consisting of tetramethoxymethyl glycoluril (Powderlink 1174) was added to the solution in a concentration of 10 parts by weight with respect to the previously described solids. The resulting solution was filtered through a PTFE membrane (0.2 μm pore size).

### Example 3

### Film Formation

The formulations prepared as described in Example 2 were spin coated onto one-inch quartz slides at 1500 rpm for 60 sec. The spin cast films were cured at 190 for 60 sec, after which the quarts slides were allowed to cool down to room temperature on a chill plate. The film thickness was about 1000 Å.

### Example 4

### Organic Solvent Resistance of a NIR Absorbing Layer of the Invention

The optical transmission of the NIR absorbing layers formed as described in Example 3 were measured in a radiation wavelength range between 400 nm and 1200 nm using a dual-beam spectrophotometer.

The above procedure was repeated for the NIR absorbing layers described in Example 3, this time rinsed after casting and baking with a solvent mixture consisting on butyl acetate and gamma-butyrolactone (70:30 mixture ratio) for 10s and spin-dried.

The spectra corresponding to the as-cast and as-rinsed NIR absorbing layers overlap perfectly up to a NIR dye-to-polymer matrix mass ratio equal to 40:60, indicating good NIR dye retention provided by the crosslinkable anion and polymer matrix.

### Example 5

### Focus Control Improvement by Use of a NIR Absorbing Layer of the Invention

A control wafer consisting on a product wafer containing buried metal layers of variable density across the individual chips was coated with a 193 nm BARC and 193 nm photoresist layers. The metal density variability across the chip was detected by the NIR leveling system of the 193 nm optical scanner as apparent height variations, despite the fact that the actual surface topography was largely flat.

A second wafer with identical embedded topography was coated with the NIR absorbing layer of Example 2 and a 193 am photoresist layer. In this case, the NIR leveling system detected a much flatter surface that was closer to the actual wafer surface due to the blocking effect of the NIR absorbing layer, which prevented the NIR radiation from reaching the underlying reflective metal layers.

While the present invention has been particularly shown and described with respect to preferred embodiments, it will be understood by those skilled in the art that the foregoing and other changes in forms and details may be made without departing from the spirit and scope of the invention. It is therefore intended that the present invention not be limited to the exact forms and details described and illustrated but fall within the scope of the appended claims.

What is claimed is:

1. A near-infrared (NIR) absorbing film composition for use in photolithography comprising:
a NIR absorbing dye having a polymethine cation and a crosslinkable anion;
a crosslinkable polymer; and
a crosslinking agent.

2. The NIR absorbing film composition of claim 1, wherein the crosslinkable anion is a monovalent organic acid anion.

3. The NIR absorbing film composition of claim 2, wherein the crosslinkable anion includes a hydroxyl, a carboxyl, a reactive ether, an amino or an imino group.

4. The NIR absorbing film composition of claim 3, wherein the crosslinkable anion includes an aromatic group.

5. The NIR absorbing film composition of claim 4, wherein the crosslinkable anion has the following structure: 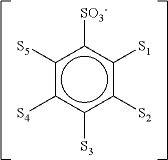
wherein S₁ to S₅ are the same or different and each independently represents a hydrogen atom, a linear or branched alkyl, a linear or branched alkoxy or a hydroxyl group, provided that at least one of S₁ to S₅ is a hydroxyl group.

6. The NIR absorbing film composition of claim 5, wherein the crosslinkable anion is selected from a group consisting of

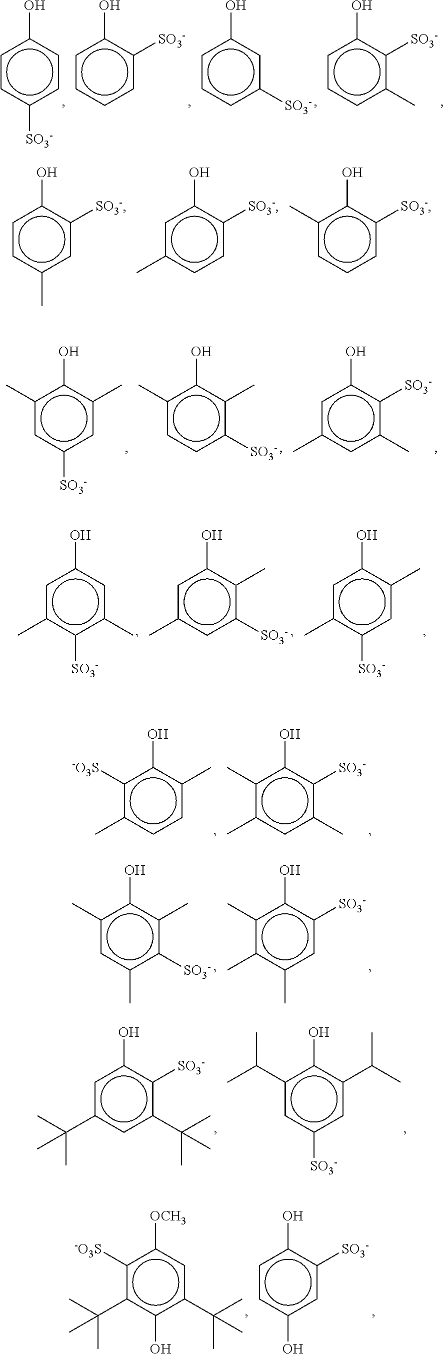

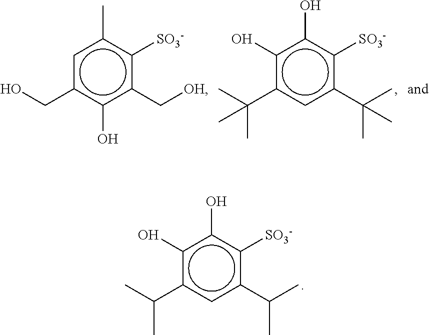

7. The NIR absorbing film composition of claim 1, wherein the polymethine cation has the following structure: 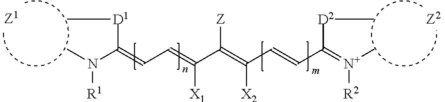
wherein m and n are the same or different and each independently represents an integer from 0 to 2; Z represents a hydrogen atom, a halide atom, a linear, branched, cyclic or polycyclic saturated or unsaturated group containing 1 to 25 carbon atoms; wherein the linear, branched, cyclic or polycyclic saturated or unsaturated group optionally includes one or more heteroatoms selected from nitrogen, oxygen, sulfur and halide atoms; X₁ and X₂ are the same or different and each independently represents a hydrogen atom, a halide atom or a linear, branched or cyclic group containing 1 to 6 carbon atoms, wherein when X₁ and X₂ are linear and branched group containing 1 to 6 carbon atoms, they can interconnect to form a five- or six-membered ring; R₁ and R₂ are the same or different and each independently represents a linear or branched alkyl group containing 1 to 6 carbon atoms, a linear or branched alkoxyalkyl group containing 1 to 6 carbon atoms or a linear or branched hydroxylalkyl group containing 1 to 6 carbon atoms; D₁ and D₂ are the same or different and each independently represents —O—, —S—, —Se—, —CH═CH—, —C(CH₃)₂—, —C—; and Z₁ and Z₂ are the same or different and each independently represents one or more fused substituted or unsubstituted aromatic rings, wherein when D₁ is —C—, interconnects with Z₁ to form one or more fused substituted or unsubstituted aromatic rings and when D₂ is —C—, D₂ interconnects with Z₂ to form one or more fused substituted or unsubstituted aromatic rings.

8. The NIR absorbing film composition of claim 7, wherein the polymethine cation is selected from a group consisting of:

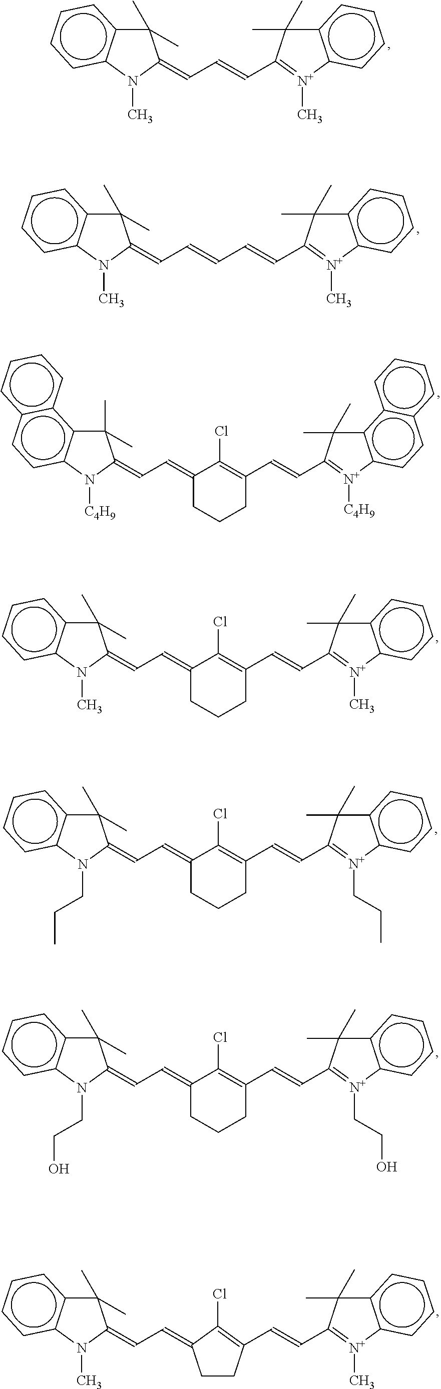

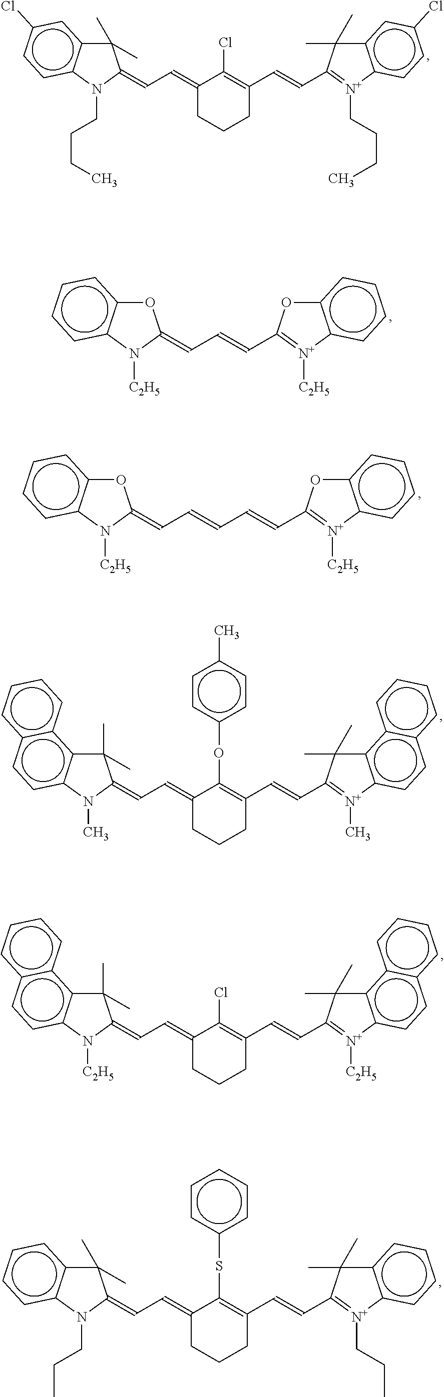

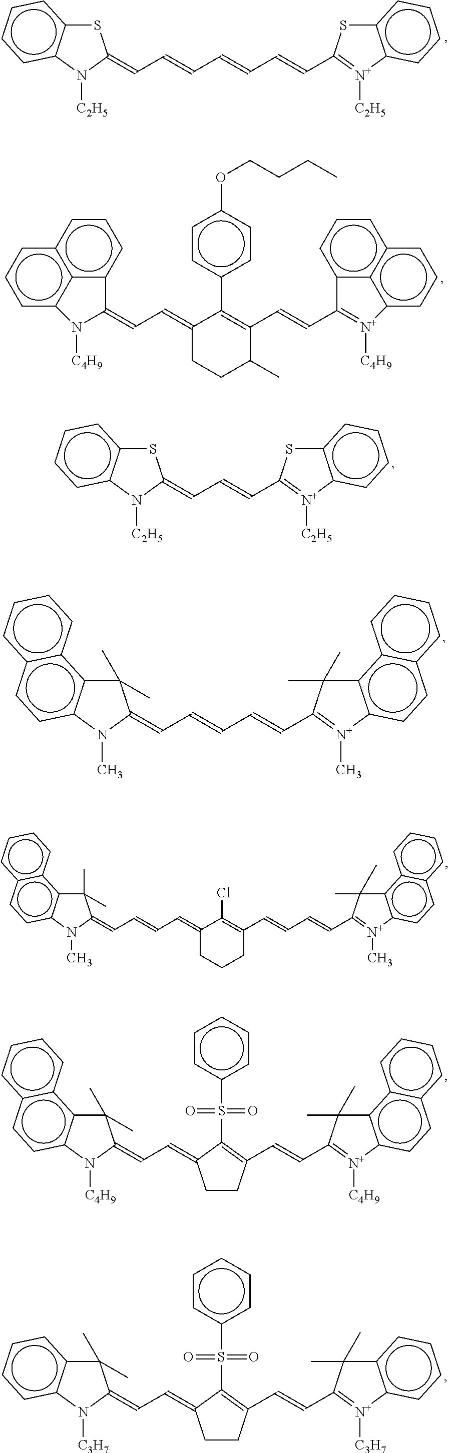

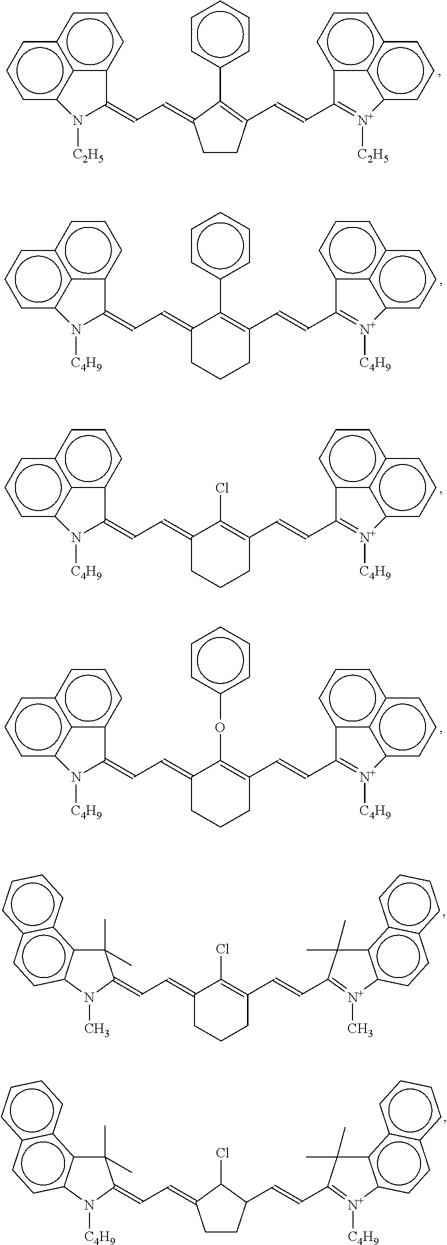

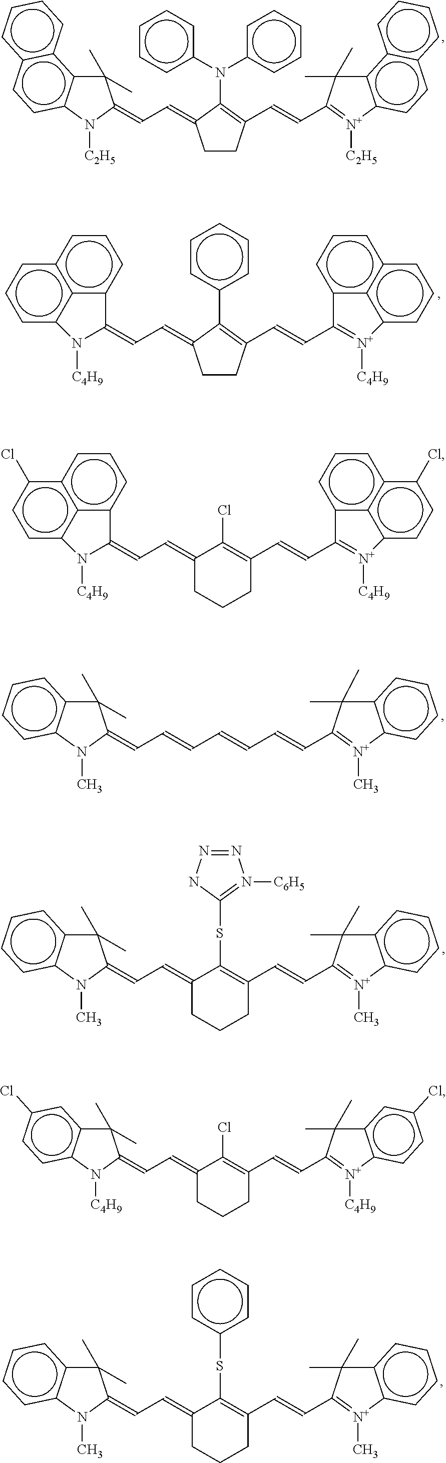

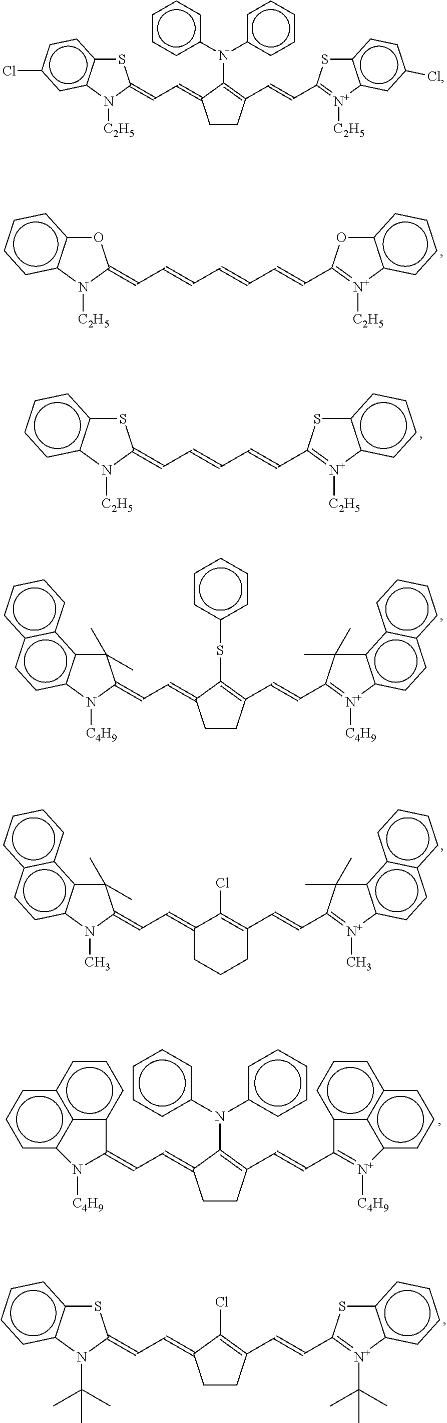

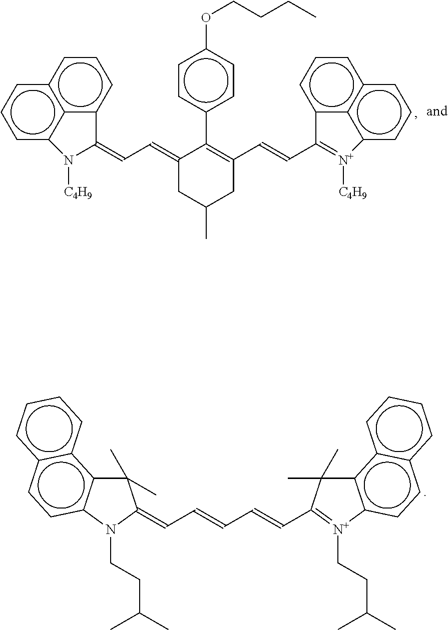

9. The NIR absorbing film composition of claim 1, wherein the NIR absorbing dye has at least one absorption peak between 500 nm and 1200 nm.

10. The NIR absorbing film composition of claim 1, wherein the crosslinkable polymer includes a monomer unit having a hydroxyl, a carboxyl, a reactive ether, an amino or an imino group.

11. The NIR absorbing film composition of claim 1, further comprising an acid generator.

12. The NIR absorbing film composition of claim 1, further comprising a casting solvent.

13. The NIR absorbing film composition of claim 1, wherein the NIR absorbing film composition is an anti-reflective layer composition.

14. A method of forming a patterned feature on a substrate, said method comprising:
providing a material layer on a substrate;
forming a NIR absorbing layer from a NW absorbing film composition on the material layer, wherein the NIR absorbing film composition includes a NIR absorbing dye having a polymethine cation and a crosslinkable anion, a crosslinkable polymer and a crosslinking agent;
forming a photoresist layer over the NIR absorbing layer;
aligning and focusing a focal plane position of the photoresist layer by sensing near-infrared emissions reflected from the substrate containing the NIR absorbing layer and photoresist layer;
patternwise exposing the photoresist layer to radiation; and
selectively removing a portion of the photoresist layer to form the patterned feature in the photoresist layer.

15. The method of claim 14, wherein the crosslinkable anion is a monovalent organic acid anion.

16. The method of claim 15, wherein the crosslinkable anion includes a hydroxyl, a carboxyl, a reactive ether, an amino or an imino group.

17. The method of claim 16, wherein the crosslinkable anion includes an aromatic group.

18. The method aim 17, wherein the crosslinkable anion has the following structure: 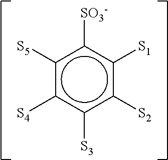
wherein S₁ to S₅ are the same or different and each independently represents a hydrogen atom, a linear or branched alkyl, a linear or branched alkoxy or a hydroxyl group, provided that at least one of S₁ to S₅ is a hydroxyl group.

19. The method of claim 18, wherein the crosslinkable anion is selected from a group consisting of:

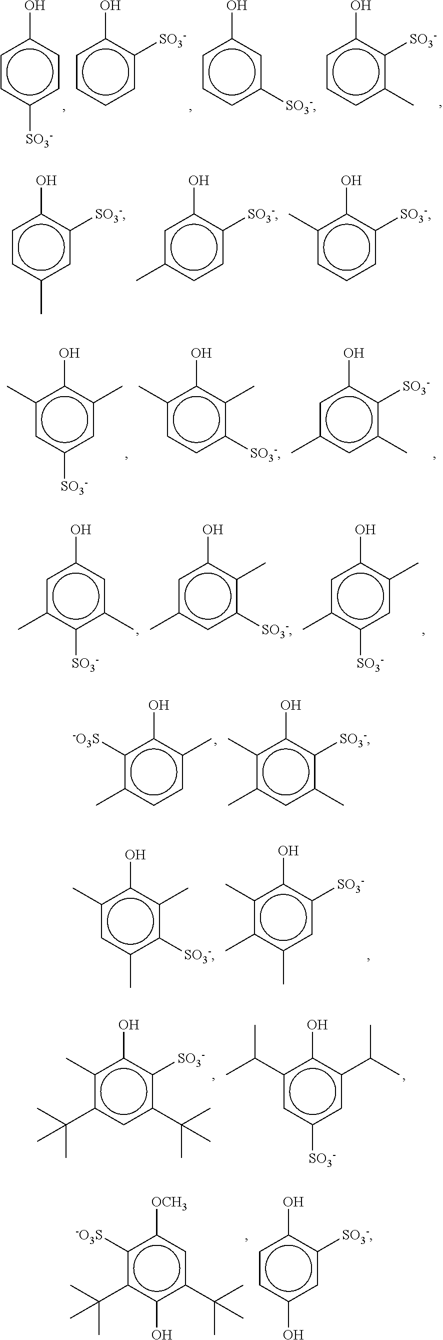

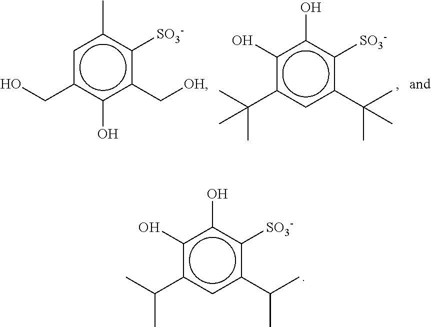

20. The method of claim 14, wherein the polymethine cation has the following structure: 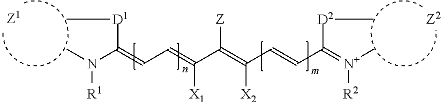
wherein m and n are the same or different and each independently represents an integer from 0 to 2; Z represents a hydrogen atom, a halide atom, a linear, branched, cyclic or polycyclic saturated or unsaturated group containing 1 to 25 carbon atoms, wherein the linear, branched, cyclic or polycyclic saturated or unsaturated group optionally includes one or more heteroatoms selected from nitrogen, oxygen, sulfur and halide atoms; X₁ and X₂ are the same or different and each independently represents a hydrogen atom, a halide atom or a linear, branched or cyclic group containing 1 to 6 carbon atoms, wherein when X₁ and X₂ are linear and branched group containing 1 to 6 carbon atoms, they can interconnect to form a five- or six-membered ring; R₁ and R₂ are the same or different and each independently represents a linear or branched alkyl group containing 1 to 6 carbon atoms, a linear or branched alkoxyalkyl group containing 1 to 6 carbon atoms or a linear or branched hydroxy group containing 1 to 6 carbon atoms; D₁ and D₂ are the same or different and each independently represents —O—, —S—, —Se—, —CH═CH—, or —C—; and Z₁ and Z₂ are the same or different and each independently represents one or more fused substituted or unsubstituted aromatic rings, wherein when D₁ is —C—, interconnects with Z₁ to form one or more fused substituted or unsubstituted aromatic rings and when D₂ is —C—, D₂ interconnects with Z₂ to form one or more fused substituted or unsubstituted aromatic rings.

21. The method of claim 20, wherein the polymethine cation is selected from a group consisting of

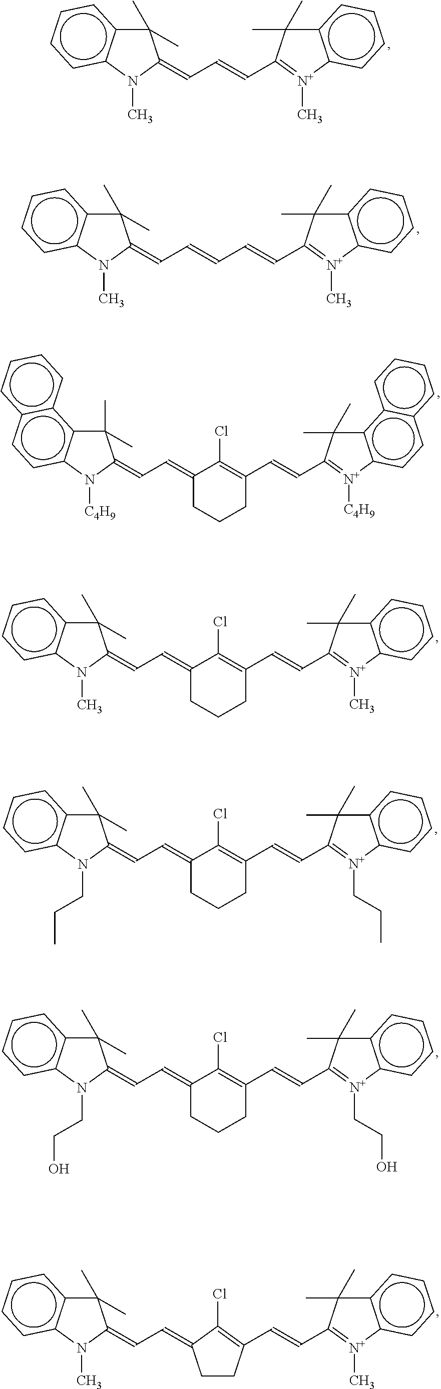

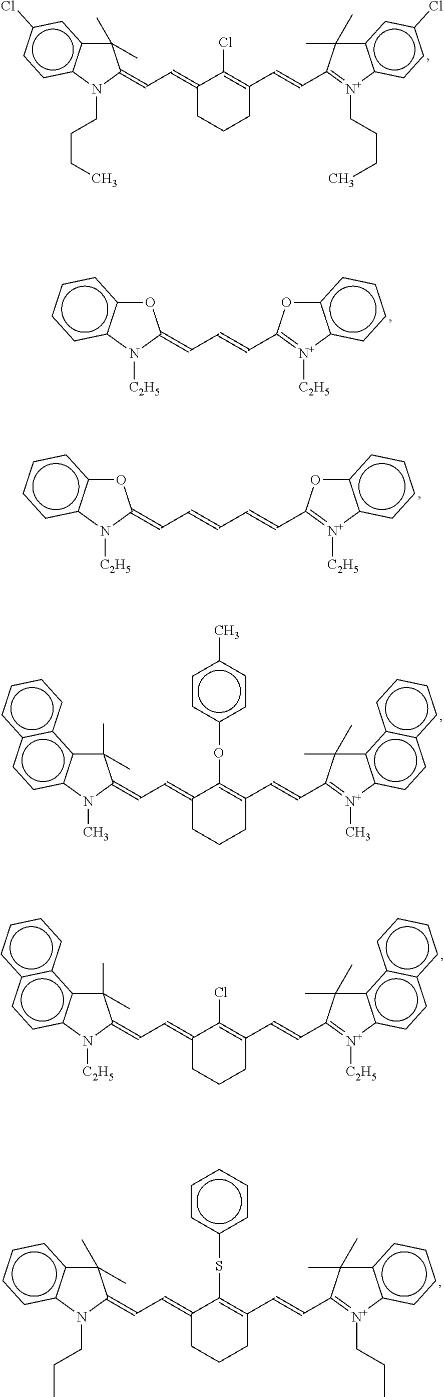

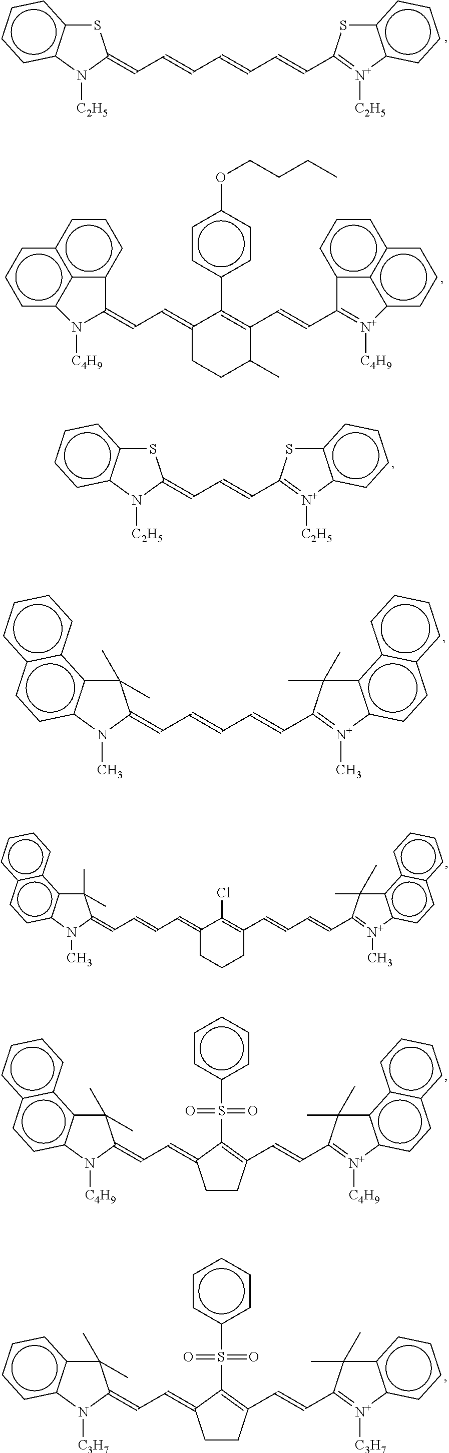

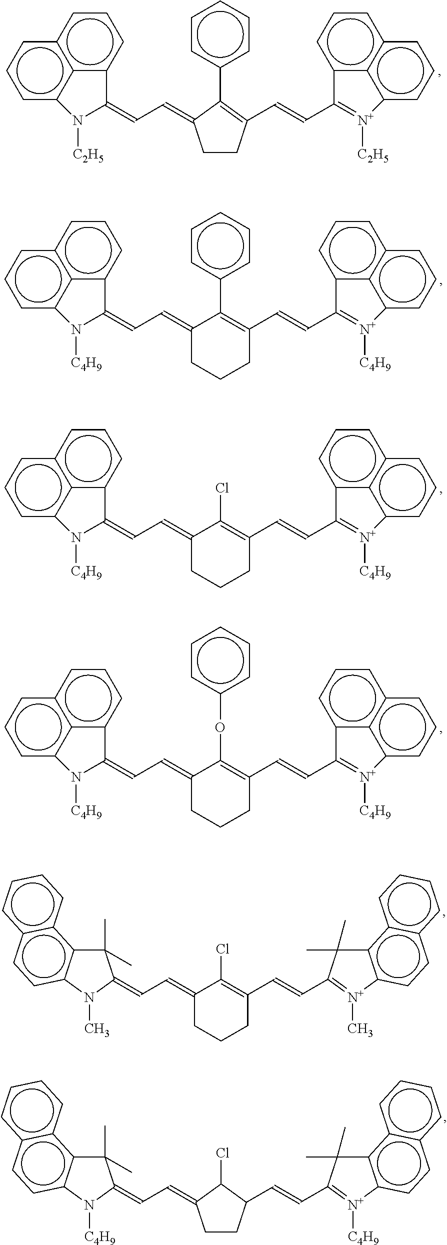

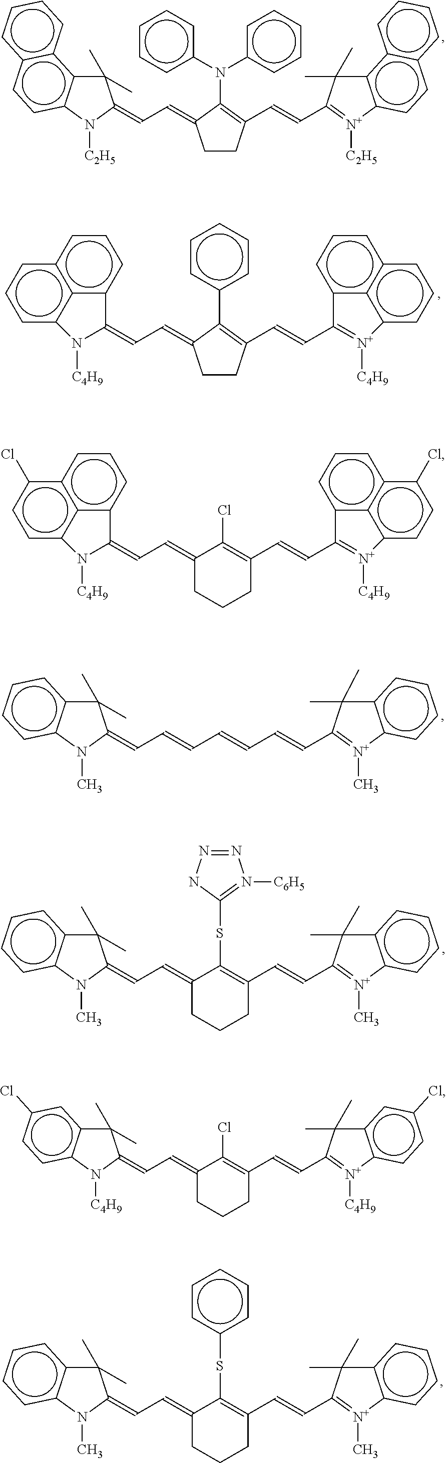

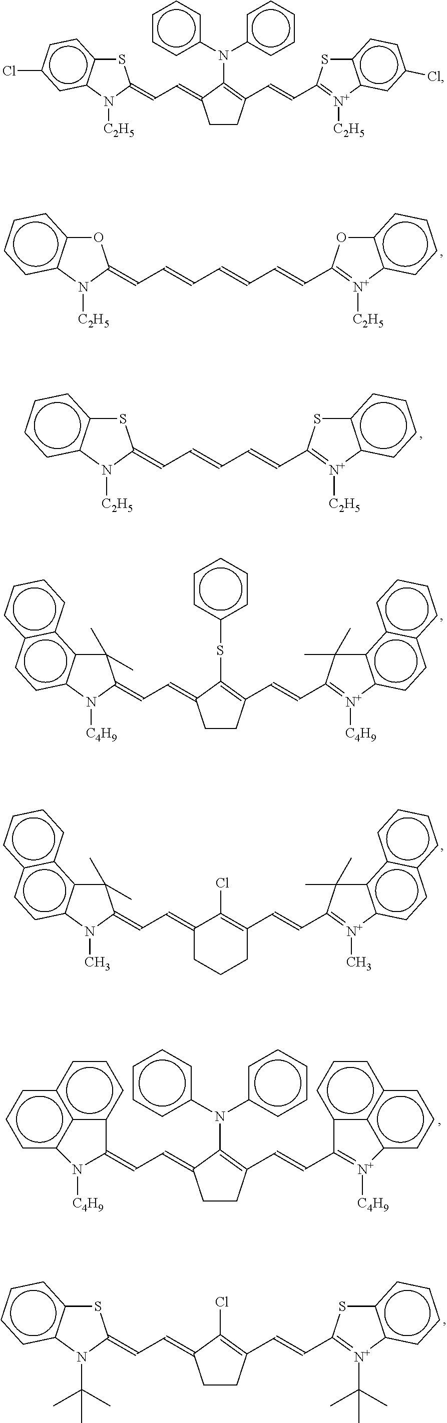

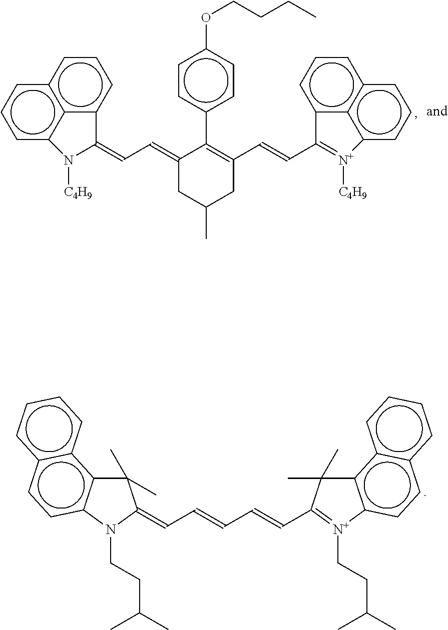

22. The method of claim 14, wherein the NIR absorbing dye has at least one absorption peak between 500 nm and 1200 nm.

23. The method of claim 14, wherein the crosslinkable polymer includes a monomer unit having a hydroxyl, a carboxyl, a reactive ether, an amino or an imino group.

24. The method of claim 14, wherein the NIR absorbing film composition further includes an acid generator.

25. The method of claim 14, wherein the NIR absorbing layer is an anti-reflective layer.

26. The method of claim 14, further comprising transferring the patterned feature to the material layer by etching or ion implanting the exposed portion of the material layer.
